(19) United States
(12) Patent Application Publication
(10) Pub. No.: US 2025/0309879 A1
(43) Pub. Date: Oct. 2, 2025

(54) OFFSET-FREE COMPARATOR CIRCUIT WITH AUTO-ZEROING

(71) Applicant: Samsung Electronics Co., Ltd., Suwon-si (KR)

(72) Inventors: Hongseok SHIN, Suwon-si (KR); Dongyeon KWAG, Suwon-si (KR); Yongjin KWON, Suwon-si (KR); Insu LEE, Suwon-si (KR); Ji-Soo CHANG, Suwon-si (KR); Hyeungjoon CHA, Suwon-si (KR); Dae-Hoon HAN, Suwon-si (KR); Heeseok HAN, Suwon-si (KR)

(73) Assignee: Samsung Electronics Co., Ltd., Suwon-si (KR)

(21) Appl. No.: 18/903,186

(22) Filed: Oct. 1, 2024

(30) Foreign Application Priority Data
Mar. 27, 2024 (KR) 10-2024-0041808

(51) Int. Cl. H03K 5/24

(52) U.S. Cl. CPC H03K 5/2481; H03K 5/249

(57) ABSTRACT

A comparator includes a switching circuit receiving first and second input voltages and outputting first and second switching voltages; first and second sampling/comparing circuits respectively receiving the first and second switching voltages and respectively outputting first and second comparison voltages; and an output circuit receiving the first and second comparison voltages and outputting an output voltage to an output terminal. The comparator operates in first and second phase in response to a clock signal. The first sampling/comparing circuit samples the second input voltage as a first sampling voltage during the first phase, and outputs a result of comparing the first input voltage with the first sampling voltage as the first comparison voltage during the second phase. The second and first sampling/comparing circuits operate with respective opposite phases. The output circuit outputs the output voltage corresponding to the second and first comparison voltages respectively during the first and second phases.

### CROSS-REFERENCE TO RELATED APPLICATIONS

This application claims priority under 35 U.S.C. § 119 to Korean Patent Application No. 10-2024-0041808 filed on Mar. 27, 2024, in the Korean Intellectual Property Office, the disclosure of which is incorporated by reference herein in its entirety.

### BACKGROUND

Some example embodiments of the present disclosure described herein relate to comparator circuits, and more particularly, relate to comparator circuits with improved performance and an improved response speed and operating methods of the comparator circuits.

A comparator circuit may receive two input signals and may output a signal corresponding to a result of comparing the two input signals thus received. Comparator circuits may be variously used in electronic devices which perform different operations depending on magnitudes of the two input signals.

To improve the performance of electronic devices including comparator circuits, a comparator with an improved response speed and improved accuracy may be required. Also, there may be required a comparator capable of providing various comparison operations based on three or more input signals, not a comparison operation of simply comparing magnitudes of two input signals.

### SUMMARY

Some example embodiments of the present disclosure provide an offset-free comparator circuit with improved response speed and an offset-free comparator circuit capable of performing calculation.

Some example embodiments provide a comparator including a switching circuit that receives a first input voltage and a second input voltage respectively from a first input terminal and a second input terminal, and outputs a first switching voltage and a second switching voltage respectively to a first switching node and a second switching node; a first sampling/comparing circuit that receives the first switching voltage from the first switching node and outputs a first comparison voltage to a first comparison node; a second sampling/comparing circuit that receives the second switching voltage from the second switching node and outputs a second comparison voltage to a second comparison node; and an output circuit that receives the first comparison voltage and the second comparison voltage respectively from the first comparison node and the second comparison node, and outputs an output voltage to an output terminal. The comparator operates in a first phase and a second phase in response to a clock signal, and each of the first input voltage and the second input voltage has a variable voltage level. The switching circuit outputs the second input voltage as the first switching voltage and outputs the first input voltage as the second switching voltage during the first phase, and the switching circuit outputs the first input voltage as the first switching voltage and outputs the second input voltage as the second switching voltage during the second phase. The first sampling/comparing circuit samples a first sampling voltage based on the second input voltage during the first phase, and the first sampling/comparing circuit outputs the first comparison voltage corresponding to a result of comparing the first input voltage with the first sampling voltage during the second phase. The second sampling/comparing circuit samples a second sampling voltage based on the second input voltage during the second phase, and the second sampling/comparing circuit outputs the second comparison voltage corresponding to a result of comparing the first input voltage with the second sampling voltage during the first phase. The output circuit outputs the output voltage corresponding to the second comparison voltage during the first phase, and the output circuit outputs the output voltage corresponding to the first comparison voltage during the second phase.

Some example embodiments further provide a comparator including a first switch connected between a first input terminal and a first switching node, the first switch receiving a first input voltage at the first input terminal; a second switch connected between a second input terminal and a second switching node, the second switch receiving a second input voltage at the second input terminal; a third switch connected between the first input terminal and the second switching node; a fourth switch connected between the second input terminal and the first switching node; a first sampling capacitor connected between the first switching node and a first node; a first inverter connected between the first node and a second node; a second inverter connected between the second node and a first comparison node; a fifth switch connected in parallel with the first inverter and between the first node and the second node; a second sampling capacitor connected between the second switching node and a third node; a third inverter connected between the third node and a fourth node; a fourth inverter connected between the fourth node and a second comparison node; a sixth switch connected in parallel with the third inverter and between the third node and the fourth node; a seventh switch connected between the first comparison node and an output terminal, the output terminal outputting an output voltage; and an eighth switch connected between the second comparison node and the output terminal. The comparator operates in a first phase and a second phase in response to a clock signal, and each of the first input voltage and the second input voltage has a variable voltage level. During the first phase the comparator turns off the first switch, the second switch, the sixth switch, and the seventh switch, and turns on the third switch, the fourth switch, the fifth switch, and the eighth switch. During the second phase the comparator turns on the first switch, the second switch, the sixth switch, and the seventh switch, and turns off the third switch, the fourth switch, the fifth switch, and the eighth switch.

Some example embodiments still further provide a comparator including a reference sampling/operating circuit that receives a first input voltage and a reference input voltage respectively from a first input terminal and a reference input terminal, and outputs an operating voltage to a middle node; a switching circuit that receives a second input voltage from a second input terminal and outputs a switching voltage to the middle node; and a sampling/comparing circuit that receives the operating voltage or the switching voltage from the middle node, and outputs an output voltage to one output terminal. The comparator operates in a first phase and a second phase in response to a clock signal, and each of the first input voltage, the second input voltage, and the reference input voltage has a variable voltage level. The reference sampling/operating circuit samples the reference input voltage during the first phase, and the reference sampling/operating circuit outputs a result of performing an operation on the first input voltage and the sampled reference input voltage as the operating voltage during the second phase. The switching circuit outputs the second input voltage as the switching voltage during the first phase, and the switching circuit provides no output to the middle node during the second phase. The sampling/comparing circuit samples a sampling voltage based on the second input voltage during the first phase, and the sampling/comparing circuit outputs the output voltage corresponding to a result of comparing the operating voltage and the sampling voltage to the output terminal during the second phase.

### BRIEF DESCRIPTION OF THE FIGURES

The above and other objects and features of the present disclosure will become apparent in view of the following detailed description of some example embodiments as made with reference to the accompanying drawings.

FIG. 1 is a block diagram illustrating an offset-free comparator circuit with an improved response speed, according to some example embodiments of the present disclosure.

FIG. 2 is a circuit diagram illustrating a first switching circuit according to some example embodiments of the present disclosure.

FIG. 3A is a circuit diagram illustrating a first sampling/comparing circuit according to some example embodiments of the present disclosure.

FIG. 3B is a circuit diagram illustrating a second sampling/comparing circuit according to some example embodiments of the present disclosure.

FIG. 4 is a circuit diagram illustrating a CMOS inverter in which an input terminal and an output terminal are short-circuited, according to some example embodiments of the present disclosure.

FIG. 5 is a circuit diagram illustrating the output circuit according to some example embodiments of the present disclosure.

FIG. 6 illustrates states which a plurality of switches included in an offset-free comparator circuit with an improved response speed have depending on a clock signal.

FIG. 7A is a circuit diagram illustrating a first-phase circuit configuration of an offset-free comparator with an improved response speed, according to some example embodiments of the present disclosure.

FIG. 7B is a circuit diagram illustrating a second-phase circuit configuration of an offset-free comparator with an improved response speed, according to some example embodiments of the present disclosure.

FIG. 8 illustrates an example in which an offset-free comparator with an improved response speed operates depending on each input voltage being variable.

FIG. 9 is a block diagram illustrating an offset-free comparator circuit capable of performing calculation, according to some example embodiments of the present disclosure.

FIG. 10A is a circuit diagram of a forward reference sampling/operating circuit according to some example embodiments of the present disclosure.

FIG. 10B is a circuit diagram of a reverse reference sampling/operating circuit according to some example embodiments of the present disclosure.

FIG. 11 is a circuit diagram illustrating a final sampling/comparing circuit according to some example embodiments of the present disclosure.

FIG. 12 is a circuit diagram illustrating a second switching circuit according to some example embodiments of the present disclosure.

FIG. 13 illustrates states which a plurality of switches included in an offset-free comparator circuit capable of performing calculation have depending on a clock signal.

FIGS. 14A and 14B are circuit diagrams illustrating a first-phase circuit configuration and a second-phase circuit configuration of an offset-free comparator capable of performing forward calculation, according to some example embodiments of the present disclosure.

FIGS. 14C and 14D are circuit diagrams illustrating a first-phase circuit configuration and a second-phase circuit configuration of an offset-free comparator capable of performing reverse calculation, according to some example embodiments of the present disclosure.

FIGS. 15A and 15B illustrate an example in which an offset-free comparator capable of performing an operation on variable input voltages operates.

FIG. 16 illustrates an example of an operating method of an offset-free comparator with improved performance.

FIG. 17 illustrates an example of an operating method of an offset-free comparator capable of performing calculation.

### DETAILED DESCRIPTION

Below, embodiments of the present disclosure will be described in detail and clearly to such an extent that one of ordinary skill in the art may easily carry out the present disclosure.

For example, throughout the following description, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

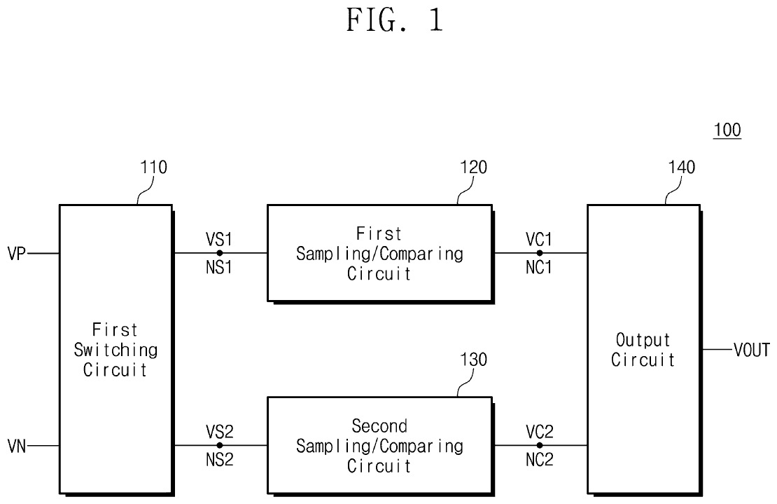

FIG. 1 is a block diagram illustrating an offset-free comparator circuit with an improved response speed, according to some example embodiments of the present disclosure. Referring to FIG. 1, an offset-free comparator 100 may include a first switching circuit 110, a first sampling/comparing circuit 120, a second sampling/comparing circuit 130, and an output circuit 140.

The offset-free comparator 100 may operate in response to a clock signal. For example, the offset-free comparator 100 may operate in one of a first phase and a second phase in response to the clock signal. For example, the offset-free comparator 100 may operate in the first phase in response to a first clock signal CLK and may operate in the second phase in response to a second clock signal /CLK. In some example embodiments, the second clock signal /CLK may be an inverted signal of the first clock signal CLK. For example, the first clock signal CLK may be a logical high signal, and the second clock signal /CLK may be a logical low signal.

The first switching circuit 110 may receive a first input voltage VP and a second input voltage VN and may output a first switching voltage VS1 and a second switching voltage VS2. The voltage level of each of the first input voltage VP and the second input voltage VN may be variable. In response to the clock signal, the first switching circuit 110 may output the first input voltage VP and the second input voltage VN as the first switching voltage VS1 or the second switching voltage VS2. For example, the first switching circuit 110 may include a plurality of switching elements. In response to switching operations of the plurality of switching elements based on the clock signal, the first switching circuit 110 may output the first input voltage VP and the second input voltage VN as the first switching voltage VS1 or the second switching voltage VS2.

For example, the first switching circuit 110 may enter the first phase in response to the first clock signal CLK. In the first phase, the first switching circuit 110 may output the first input voltage VP as the second switching voltage VS2 and may output the second input voltage VN as the first switching voltage VS1. For example, the first switching circuit 110 may enter the second phase in response to the second clock signal /CLK. In the second phase, the first switching circuit 110 may output the first input voltage VP as the first switching voltage VS1 and may output the second input voltage VN as the second switching voltage VS2.

The first sampling/comparing circuit 120 may receive the first switching voltage VS1 from the first switching circuit 110 and may output a first comparison voltage VC1. The first sampling/comparing circuit 120 may sample the first switching voltage VS1 in response to the clock signal and may output the first comparison voltage VC1. For example, the first sampling/comparing circuit 120 may include at least one switching element. In response to a switching operation of the switching element based on the clock signal, the first sampling/comparing circuit 120 may sample the first switching voltage VS1 and may output the first comparison voltage VC1. For example, the first comparison voltage VC1 may be a voltage corresponding to a result of comparing the first input voltage VP and the second input voltage VN.

For example, the first sampling/comparing circuit 120 may enter the first phase in response to the first clock signal CLK. The first sampling/comparing circuit 120 may sample the first switching voltage VS1 in the first phase. For example, the first sampling/comparing circuit 120 may enter the second phase in response to the second clock signal /CLK. The first sampling/comparing circuit 120 may output the first comparison voltage VC1 corresponding to a result of comparing the first input voltage VP and the second input voltage VN in the second phase.

The second sampling/comparing circuit 130 may receive the second switching voltage VS2 from the first switching circuit 110 and may output a second comparison voltage VC2. The second sampling/comparing circuit 130 may sample the second switching voltage VS2 in response to the clock signal and may output the second comparison voltage VC2. For example, the second sampling/comparing circuit 130 may include at least one switching element. In response to a switching operation of the switching element based on the clock signal, the second sampling/comparing circuit 130 may sample the second switching voltage VS2 and may output the second comparison voltage VC2. In some example embodiments, the second comparison voltage VC2 may be a voltage corresponding to a result of comparing the first input voltage VP and the second input voltage VN.

For example, the second sampling/comparing circuit 130 may enter the first phase in response to the first clock signal CLK. The second sampling/comparing circuit 130 may output the second comparison voltage VC2 corresponding to a result of comparing the first input voltage VP and the second input voltage VN in the first phase. For example, the second sampling/comparing circuit 130 may enter the second phase in response to the second clock signal /CLK. The second sampling/comparing circuit 130 may sample the second switching voltage VS2 in the second phase.

The output circuit 140 may receive the first comparison voltage VC1 from the first sampling/comparing circuit 120, may receive the second comparison voltage VC2 from the second sampling/comparing circuit 130, and may output an output voltage VOUT. For example, the output circuit 140 may include a plurality of switching elements. In response to switching operations of the plurality of switching elements based on the clock signal, the output circuit 140 may output one of the first comparison voltage VC1 and the second comparison voltage VC2 as the output voltage VOUT.

For example, the output circuit 140 may enter the first phase in response to the first clock signal CLK. The output circuit 140 may output the second comparison voltage VC2 as the output voltage VOUT in the first phase. For example, the output circuit 140 may enter the second phase in response to the second clock signal /CLK. The output circuit 140 may output the first comparison voltage VC1 as the output voltage VOUT in the second phase.

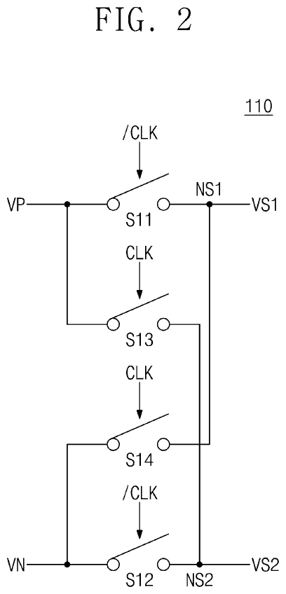

FIG. 2 is a circuit diagram illustrating the first switching circuit 110 according to some example embodiments of the present disclosure. Referring to FIG. 1, the first switching circuit 110 may include a first switch S11, a second switch S12, a third switch S13, and a fourth switch S14.

The first switching circuit 110 may receive the first input voltage VP from a first input terminal, may receive the second input voltage VN from a second input terminal, may output the first switching voltage VS1 to a first switching node NS1, and may output the second switching voltage VS2 to a second switching node NS2.

Each of the first switch S11, the second switch S12, the third switch S13, and the fourth switch S14 may be one of the plurality of switching elements of the first switching circuit 110. The first switch S11 may be connected between the first input terminal and the first switching node NS1. The second switch S12 may be connected between the second input terminal and the second switching node NS2. The third switch S13 may be connected between the first input terminal and the second switching node NS2. The fourth switch S14 may be connected between the second input terminal and the first switching node NS1.

For example, in the first phase, the first switch S11 and the second switch S12 may be turned off, and the third switch S13 and the fourth switch S14 may be turned on. For example, the first switch S11 and the second switch S12 may be turned off in response to the first clock signal CLK, and the third switch S13 and the fourth switch S14 may be turned on in response to the first clock signal CLK. In the first phase, the first switching circuit 110 may output the first input voltage VP received from the first input terminal to the second switching node NS2 through the third switch S13. In the first phase, the first switching circuit 110 may output the second input voltage VN received from the second input terminal to the first switching node NS1 through the fourth switch S14. In the first phase, the first switching voltage VS1 may be the second input voltage VN, and the second switching voltage VS2 may be the first input voltage VP.

For example, in the second phase, the first switch S11 and the second switch S12 may be turned on, and the third switch S13 and the fourth switch S14 may be turned off. For example, the first switch S11 and the second switch S12 may be turned on in response to the second clock signal /CLK, and the third switch S13 and the fourth switch S14 may be turned off in response to the second clock signal /CLK. In the second phase, the first switching circuit 110 may output the first input voltage VP received from the first input terminal to the first switching node NS1 through the first switch S11. In the second phase, the first switching circuit 110 may output the second input voltage VN received from the second input terminal to the second switching node NS2 through the second switch S12. In the second phase, the first switching voltage VS1 may be the first input voltage VP, and the second switching voltage VS2 may be the second input voltage VN.

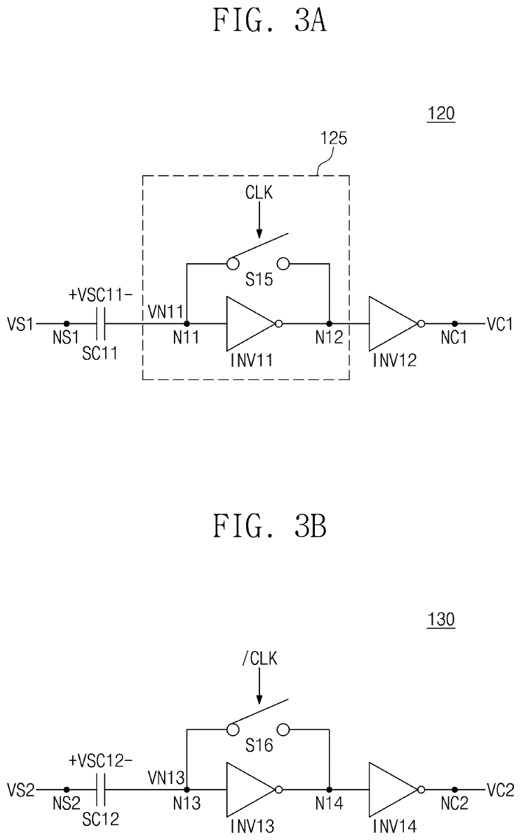

FIG. 3A is a circuit diagram illustrating the first sampling/comparing circuit 120 according to some example embodiments of the present disclosure. Referring to FIG. 3A, the first sampling/comparing circuit 120 may include a first sampling capacitor SCI1, a first inverter INV11, a second inverter INV12, and a fifth switch S15.

The first sampling/comparing circuit 120 may receive the first switching voltage VS1 from the first switching node NS1 and may output the first comparison voltage VC1 to the first comparison node NC1.

The first sampling capacitor SC11 may be connected between the first switching node NS1 and a first node N11. The first inverter INV11 may be connected between the first node N11 and a second node N12. The second inverter INV12 may be connected between the second node N12 and a first comparison node NC1. The fifth switch S15 may be a switching element of the first sampling/comparing circuit 120. The fifth switch S15 and the first inverter INV11 may be connected in parallel between the first node N11 and the second node N12.

For example, in the first phase, the fifth switch S15 may be turned on. For example, the fifth switch S15 may be turned on in response to the first clock signal CLK. In the first phase, the first sampling/comparing circuit 120 may sample a first sampling voltage VSC11 based on the first switching voltage VS1 received from the first switching node NS1. For example, in the first phase, when the fifth switch S15 is turned on, the first node N11 and the second node N12 may be short-circuited, and thus, an offset voltage VOS11 of the first inverter INV11 may be removed. That is, in the first phase, the first inverter INV11 may be set to an auto-zeroing state, and thus, the offset voltage VOS11 of the first inverter INV11 may be removed. Accordingly, in the first phase, the first sampling/comparing circuit 120 may sample, as the first sampling voltage VSC11, a voltage obtained by subtracting the offset voltage VOS11 of the first inverter INV11 from the first switching voltage VS1 by using the first sampling capacitor SC11.

In some example embodiments, the offset voltage VOS11 of the first inverter INV11 may be a first node voltage VN11 or a second node voltage when the first input terminal and the second input terminal of the offset-free comparator 100 are short-circuited.

Referring to FIGS. 2 and 3A, in the first phase, because the first switching voltage VS1 is the second input voltage VN, the first sampling capacitor SCI1 may sample, as the first sampling voltage VSC11, a voltage obtained by subtracting the offset voltage VOS11 of the first inverter INV11 from the second input voltage VN (e.g., VSC11=VN−VOS11).

For example, in the second phase, the fifth switch S15 may be turned off. For example, the fifth switch S15 may be turned off in response to the second clock signal /CLK. In the second phase, the first sampling/comparing circuit 120 may output the first comparison voltage VC1 corresponding to a result of comparing the first switching voltage VS1 received from the first switching node NS1 and the first sampling voltage VSC11. For example, in the second phase, the first node voltage VN11 may be a voltage obtained by subtracting the first sampling voltage VSC11 from the first switching voltage VS1, and the first comparison voltage VC1 may correspond to a voltage in which the offset voltage VOS11 is removed from the first node voltage VN11.

Referring to FIGS. 2 and 3A, in the second phase, because the first switching voltage VS1 is the first input voltage VP, the first node voltage VN11 may be a voltage obtained by subtracting the first sampling voltage VSC11 from the first input voltage VP, that is, may be a voltage corresponding to ((the first input voltage VP minus the second input voltage VN) plus the offset voltage VOS11 of the first inverter INV11) (e.g., VN11=(VP−VN)+VOS11). Because the offset voltage VOS11 is already applied to the first node voltage VN11, the first comparison voltage VC1 may be free from the offset voltage VOS11 of the first inverter INV11.

For example, when the first input voltage VP is greater than the second input voltage VN, the first comparison voltage VC1 may be logical high (e.g., have a logical high level). As another example, when the first input voltage VP is smaller than the second input voltage VN, the first comparison voltage VC1 may be logical low (e.g., have a logical low level).

FIG. 3B is a circuit diagram illustrating the second sampling/comparing circuit 130 according to some example embodiments of the present disclosure. Referring to FIG. 3B, the second sampling/comparing circuit 130 may include a second sampling capacitor SC12, a third inverter INV13, a fourth inverter INV14, and a sixth switch S16.

A configuration and an operation of the second sampling/comparing circuit 130 may be the same as those of the first sampling/comparing circuit 120 except that the second switching voltage VS2 is received from the second switching node NS2, the second comparison voltage VC2 is output from a second comparison node NC2, and the second sampling/comparing circuit 130 operates in response to the second clock signal /CLK. Thus, additional description will be omitted to avoid redundancy.

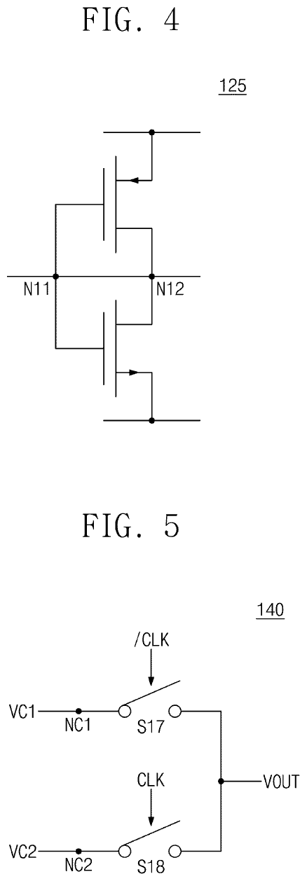

FIG. 4 is a circuit diagram illustrating a CMOS inverter in which an input terminal and an output terminal are short-circuited, according to some example embodiments of the present disclosure. Referring to FIG. 4, a CMOS inverter may include a PMOS transistor and an NMOS transistor.

Referring to FIGS. 3A and 4, in the first phase of the first sampling/comparing circuit 120, when the fifth switch S15 is turned on, an input terminal and an output terminal of the first inverter INV11, that is, the first node N11 and the second node N12 may be short-circuited. Herein, when the first inverter INV11 is a CMOS inverter, the first inverter INV11 between the first node N11 and the second node N12 may correspond to the circuit diagram 125 illustrated in FIG. 4.

Likewise, referring to FIGS. 3B and 4, in the second phase of the second sampling/comparing circuit 130, when the sixth switch S16 is turned on, an input terminal and an output terminal of the third inverter INV13, that is, a third node N13 and a fourth node N14 may be short-circuited. Herein, when the third inverter INV13 is a CMOS inverter, the third inverter INV13 between the third node N13 and the fourth node N14 may correspond to the circuit diagram illustrated in FIG. 4.

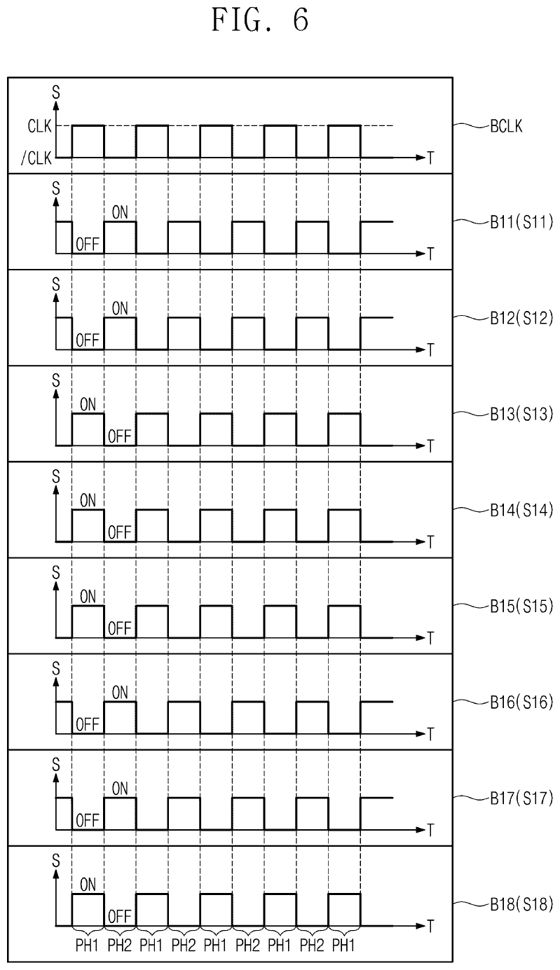

FIG. 5 is a circuit diagram illustrating the output circuit 140 according to some example embodiments of the present disclosure. Referring to FIG. 5, the output circuit 140 may include a seventh switch S17 and an eighth switch S18.

The output circuit 140 may receive the first comparison voltage VC1 from the first comparison node NC1, may receive the second comparison voltage VC2 from the second comparison node NC2, and may output the output voltage VOUT to the output terminal.

Each of the seventh switch S17 and the eighth switch S18 may be one of the plurality of switching elements of the output circuit 140. The seventh switch S17 may be connected between the first comparison node NC1 and the one output terminal. The eighth switch S18 may be connected between the second comparison node NC2 and the one output terminal.

For example, in the first phase, the seventh switch S17 may be turned off, and the eighth switch S18 may be turned on. For example, the seventh switch S17 may be turned off in response to the first clock signal CLK, and the eighth switch S18 may be turned on in response to the first clock signal CLK. In the first phase, the output circuit 140 may output the second comparison voltage VC2 received from the second comparison node NC2 to the one output terminal through the eighth switch S18 as the output voltage VOUT. For example, when the first input voltage VP is greater than the second input voltage VN, the output voltage VOUT may be logical high. As another example, when the first input voltage VP is smaller than the second input voltage VN, the output voltage VOUT may be logical low.

For example, in the second phase, the seventh switch S17 may be turned on, and the eighth switch S18 may be turned off. For example, the seventh switch S17 may be turned on in response to the first clock signal CLK, and the eighth switch S18 may be turned off in response to the first clock signal CLK. In the second phase, the output circuit 140 may output the first comparison voltage VC1 received from the first comparison node NC1 to the one output terminal through the seventh switch S17 as the output voltage VOUT. For example, when the first input voltage VP is greater than the second input voltage VN, the output voltage VOUT may be logical high. As another example, when the first input voltage VP is smaller than the second input voltage VN, the output voltage VOUT may be logical low

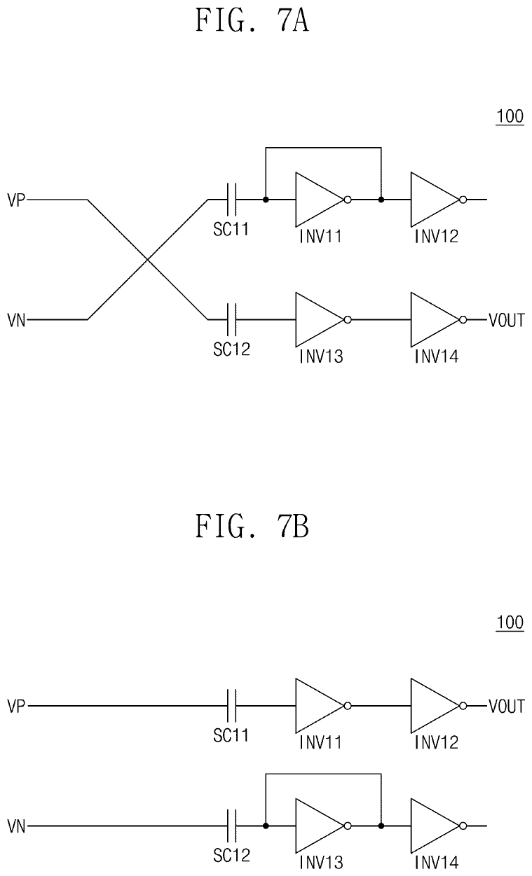

FIG. 6 illustrates states which a plurality of switches included in an offset-free comparator circuit with an improved response speed have depending on a clock signal. In some example embodiments, states of the first to eighth switches S11 to S18 according to the first clock signal CLK and the second clock signal /CLK are illustrated in FIG. 6. A clock signal box BCLK shows a state of the clock signal. A first box B11 shows a state of the first switch S11. A second box B12 shows a state of the second switch S12. A third box B13 shows a state of the third switch S13. A fourth box B14 shows a state of the fourth switch S14. A fifth box B15 shows a state of the fifth switch S15. A sixth box B16 shows a state of the sixth switch S16. A seventh box B17 shows a state of the seventh switch S17. An eighth box B18 shows a state of the eighth switch S18. In FIG. 6, the horizontal axis represents a time “T”, and the vertical axis represents a state “S”.

Referring to FIG. 6, the states of the first to eighth switches S11 to S18 may be repeatedly changed in response to the first clock signal CLK and the second clock signal /CLK.

The first clock signal CLK and the second clock signal /CLK may be mutually repeated. The second clock signal /CLK may be an inverted signal of the first clock signal CLK. For example, the first clock signal CLK may be a logical high signal, and the second clock signal /CLK may be a logical low signal. For example, a response period to the first clock signal CLK may be a first phase PH1, and a response period to the second clock signal /CLK may be a second phase PH2.

The first switch S11, the second switch S12, the sixth switch S16, and the seventh switch S17 may be turned off in response to the first clock signal CLK and may be turned on in response to the second clock signal /CLK. The third switch S13, the fourth switch S14, the fifth switch S15, and the eighth switch S18 may be turned on in response to the first clock signal CLK and may be turned off in response to the second clock signal /CLK.

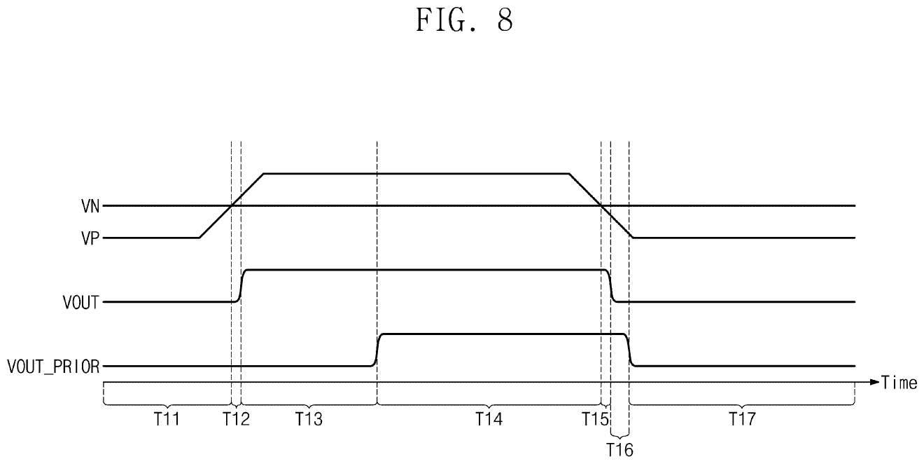

FIGS. 7A and 7B are circuit diagrams respectively illustrating a first-phase circuit configuration and a second-phase circuit configuration of an offset-free comparator with an improved response speed, according to some example embodiments of the present disclosure.

Referring to FIGS. 7A and 7B, in the first phase, the offset-free comparator 100 may sample the first sampling voltage VSC11, which is based on the second input voltage VN, by using the first sampling capacitor SC11 and may output the output voltage VOUT corresponding to a comparison result of the first input voltage VP and the second input voltage VN to one output terminal through the second sampling capacitor SC12, the third inverter INV13, and the fourth inverter INV14.

Also, in the second phase, the offset-free comparator 100 may sample the second sampling voltage VSC12, which is based on the second input voltage VN, by using the second sampling capacitor SC12 and may output the output voltage VOUT corresponding to a comparison result of the first input voltage VP and the second input voltage VN to one output terminal through the first inverter INV11 and the second inverter INV12.

Accordingly, the offset-free comparator 100 removing an offset voltage by using auto-zeroing may output the accurate output voltage VOUT corresponding to the comparison result of the first input voltage VP and the second input voltage VN. Also, in both the first phase and the second phase, the offset-free comparator 100 may continuously output the output voltage VOUT corresponding to the comparison result of the first input voltage VP and the second input voltage VN. That is, as the offset-free comparator 100 outputs the output voltage VOUT corresponding to the comparison result of the first input voltage VP and the second input voltage VN, the offset-free comparator 100 may have a more improved response speed.

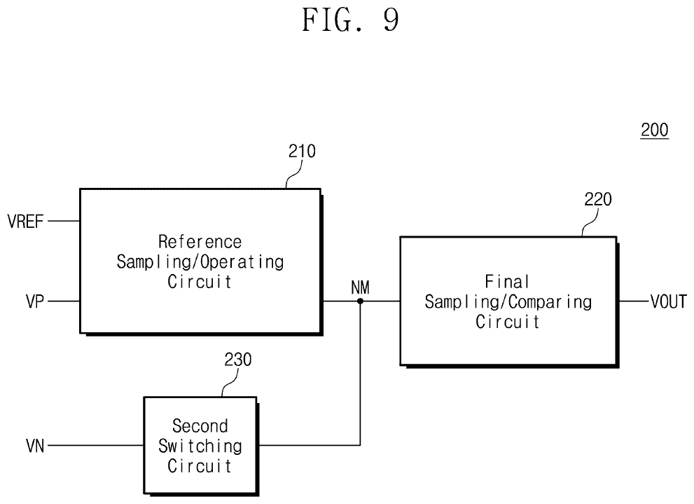

FIG. 8 illustrates an example in which an offset-free comparator with an improved response speed operates depending on each input voltage being variable. In FIG. 8, the horizontal axis represents a time, and the vertical axis represents a voltage. In some example embodiments, an example of the first input voltage VP, the second input voltage VN, the output voltage VOUT of the offset-free comparator 100 with an improved response speed, and the output voltage VOUT_PRIOR of a conventional analog comparator over time are illustrated in FIG. 8.

Referring to FIG. 8, the output voltage VOUT of the offset-free comparator 100 and the output voltage VOUT_PRIOR of the conventional analog comparator are logical high or logical low based on magnitudes of the first input voltage VP and the second input voltage VN whose voltage levels are variable. For convenience of description, an example in which the second input voltage VN is fixed is illustrated in FIG. 8, but the present disclosure is not limited thereto.

In a first time interval T11, the first input voltage VP may be smaller than the second input voltage VN, and the output voltage VOUT of the offset-free comparator 100 and the output voltage VOUT_PRIOR of the conventional analog comparator are logical low.

In a second time interval T12, the first input voltage VP may be greater than the second input voltage VN, and the output voltage VOUT of the offset-free comparator 100 and the output voltage VOUT_PRIOR of the conventional analog comparator are logical low.

In a third time interval T13, the first input voltage VP may be greater than the second input voltage VN, the output voltage VOUT of the offset-free comparator 100 may be logical high (e.g., may have a logical high level), and the output voltage VOUT_PRIOR of the conventional analog comparator may be logical low (e.g., may have a logical low level).

In a fourth time interval T14, the first input voltage VP may be greater than the second input voltage VN, and the output voltage VOUT of the offset-free comparator 100 and the output voltage VOUT_PRIOR of the conventional analog comparator are logical high.

In a fifth time interval T15, the first input voltage VP may be smaller than the second input voltage VN, and the output voltage VOUT of the offset-free comparator 100 and the output voltage VOUT_PRIOR of the conventional analog comparator are logical high.

In a sixth time interval T16, the first input voltage VP may be smaller than the second input voltage VN, the output voltage VOUT of the offset-free comparator 100 may be logical low, and the output voltage VOUT_PRIOR of the conventional analog comparator are logical high.

In a seventh time interval T17, the first input voltage VP may be smaller than the second input voltage VN, and the output voltage VOUT of the offset-free comparator 100 and the output voltage VOUT_PRIOR of the conventional analog comparator are logical low.

Herein, because the offset-free comparator 100 outputs the output voltage VOUT in response to each of the first clock signal CLK and the second clock signal /CLK, in the second time period T12, the output voltage VOUT may be changed to “logical high” within half the period of the clock signal after the first input voltage VP is greater than the second input voltage VN. That is, the second time interval T12 may be shorter than half the period of the clock signal. Likewise, in the fifth time period T15, the output voltage VOUT may be changed to “logical low” within half the period of the clock signal after the first input voltage VP is smaller than the second input voltage VN. That is, the fifth time interval T15 may be shorter than half the period of the clock signal.

Also, the first sampling/comparing circuit 120 may receive the first input voltage VP from the first switching node NS1 immediately after (or simultaneously when) the first inverter INV11 is released from the auto-zeroing state while entering the second phase from the first phase, and thus, a speed at which the output voltage VOUT of the offset-free comparator 100 changes may be improved. Likewise, the second sampling/comparing circuit 130 may receive the first input voltage VP from the second switching node NS2 immediately after (or simultaneously when) the third inverter INV13 is released from the auto-zeroing state while entering the first phase from the second phase, and thus, a speed at which the output voltage VOUT of the offset-free comparator 100 changes may be improved.

Accordingly, the second time interval T12, that is, a time interval from a point in time when the first input voltage VP is greater than the second input voltage VN to a point in time when the offset-free comparator 100 outputs the output voltage VOUT corresponding to the comparison result of the first input voltage VP and the second input voltage VN, that is, a logical high signal may be shorter than that of the conventional analog comparator. Likewise, the fifth time interval T15, that is, a time interval from a point in time when the first input voltage VP is smaller than the second input voltage VN to a point in time when the offset-free comparator 100 outputs the output voltage VOUT corresponding to the comparison result of the first input voltage VP and the second input voltage VN, that is, a logical low signal may be shorter than that of the conventional analog comparator.

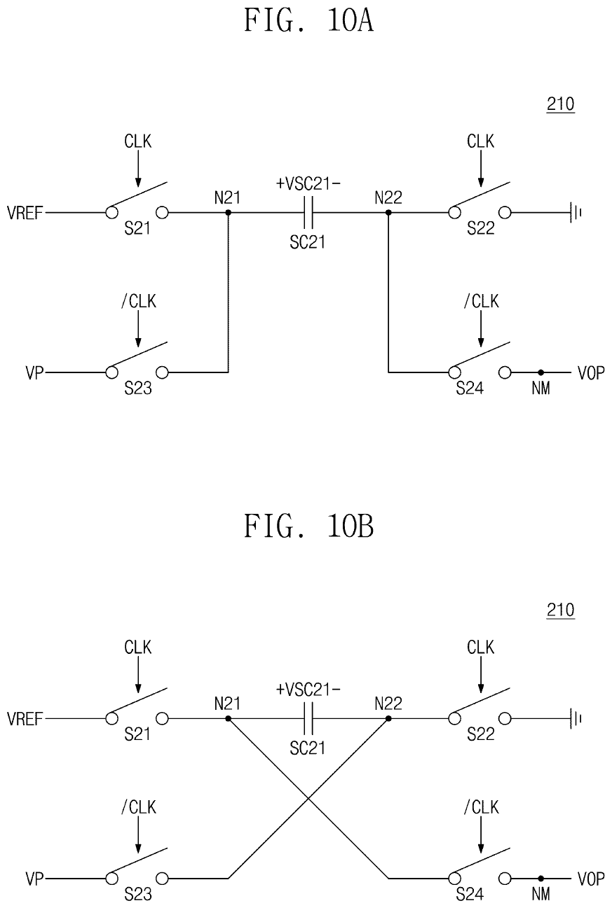

FIG. 9 is a block diagram illustrating an offset-free comparator circuit capable of performing calculation, according to some example embodiments of the present disclosure. Referring to FIG. 9, an offset-free comparator 200 may include a reference sampling/operating circuit 210, a final sampling/comparing circuit 220, and a second switching circuit 230.

The offset-free comparator 200 may operate in response to a clock signal. For example, the offset-free comparator 200 may operate in one of the first phase and the second phase in response to the clock signal. For example, the offset-free comparator 200 may operate in the first phase in response to the first clock signal CLK and may operate in the second phase in response to the second clock signal /CLK. Herein, the second clock signal /CLK may be an inverted signal of the first clock signal CLK. For example, the first clock signal CLK may be a logical high signal, and the second clock signal /CLK may be a logical low signal.

The reference sampling/operating circuit 210 may receive the first input voltage VP and a reference input voltage VREF and may output an operating voltage. The voltage level of each of the first input voltage VP and the reference input voltage VREF may be variable. The reference sampling/operating circuit 210 may sample the first input voltage VP in response to the clock signal and may output the operating voltage VOP. For example, the reference sampling/operating circuit 210 may include a plurality of switching elements. In response to switching of the plurality of switching elements based on the clock signal, the reference sampling/operating circuit 210 may sample the reference input voltage VREF and may output the operating voltage VOP. In some example embodiments, the operating voltage VOP may be a voltage corresponding to a result of an operation on the first input voltage VP and the reference input voltage VREF.

For example, the reference sampling/operating circuit 210 may enter the first phase in response to the first clock signal CLK. The reference sampling/operating circuit 210 may sample the reference input voltage VREF in the first phase. For example, the reference sampling/operating circuit 210 may enter the second phase in response to the second clock signal /CLK. The reference sampling/operating circuit 210 may output the operating voltage VOP corresponding to a result of an operation on the first input voltage VP and the reference input voltage VREF in the second phase.

The second switching circuit 230 may receive the second input voltage VN and may output a switching voltage. The voltage level of the second input voltage VN may be variable. The second switching circuit 230 may output the second input voltage VN as the switching voltage VS in response to the clock signal. For example, the second switching circuit 230 may include at least one switching element. In response to a switching operation of the switching element based on the clock signal, the second switching circuit 230 may output the second input voltage VN as the switching voltage VS.

For example, the second switching circuit 230 may enter the first phase in response to the first clock signal CLK. The second switching circuit 230 may output the second input voltage VN as the switching voltage VS in the first phase. For example, the second switching circuit 230 may enter the second phase in response to the second clock signal /CLK. The second switching circuit 230 may not output the switching voltage VS in the second phase.

Accordingly, in the first phase, the reference sampling/operating circuit 210 may not output a voltage to a middle node NM, and the second switching circuit 230 may output the switching voltage VS to the middle node NM. Also, in the second phase, the reference sampling/operating circuit 210 may output the operating voltage VOP to the middle node NM, and the second switching circuit 230 may not output a voltage to the middle node NM.

The final sampling/comparing circuit 220 may receive the operating voltage VOP and the switching voltage VS from the reference sampling/operating circuit 210 and the second switching circuit 230, respectively, and may output the output voltage VOUT. The final sampling/comparing circuit 220 may sample the switching voltage VS in response to the clock signal and may output the output voltage VOUT. For example, the final sampling/comparing circuit 220 may include at least one switching element. In response to a switching operation of the switching element based the clock signal, the final sampling/comparing circuit 220 may sample the switching voltage VS and may output the output voltage VOUT. In some example embodiments, the output voltage VOUT may be a voltage corresponding to a result of comparing the operating voltage VOP and the second input voltage VN.

For example, the final sampling/comparing circuit 220 may enter the first phase in response to the first clock signal CLK. The reference sampling/comparing circuit 220 may sample the switching voltage VS in the first phase. For example, the final sampling/comparing circuit 220 may enter the second phase in response to the second clock signal /CLK. The final sampling/comparing circuit 220 may output the output voltage VOUT corresponding to a result of comparing the operating voltage VOP and the second input voltage VN in the second phase.

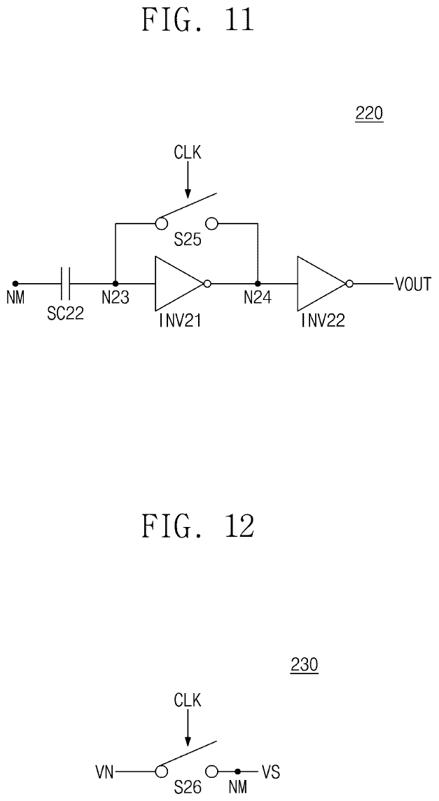

FIG. 10A is a circuit diagram illustrating a forward reference sampling/operating circuit according to some example embodiments of the present disclosure. Referring to FIG. 10A, the reference sampling/operating circuit 210 may include a first switch S21, a second switch S22, a third switch S23, a fourth switch S24, and a first sampling capacitor SC21.

The reference sampling/operating circuit 210 may receive the first input voltage VP from a first input terminal, may receive the reference input voltage VREF from a reference input terminal, and may output the operating voltage VOP to the middle node NM.

Each of the first switch S21, the second switch S22, the third switch S23, and the fourth switch S24 may be one of a plurality of switching elements of the reference sampling/operating circuit 210. The first switch S21 may be connected between the reference input terminal and a first node N21. The second switch S22 may be connected between a second node N22 and a ground terminal. The third switch S23 may be connected between the first input terminal and the first node N21. The fourth switch S24 may be connected between the second node N22 and the middle node NM. The first sampling capacitor SC21 may be connected between the first node N21 and the second node N22.

For example, in the first phase, the first switch S21 and the second switch S22 may be turned on, and the third switch S23 and the fourth switch S24 may be turned off. For example, the first switch S21 and the second switch S22 may be turned on in response to the first clock signal CLK, and the third switch S23 and the fourth switch S24 may be turned off in response to the first clock signal CLK. In the first phase, the reference sampling/operating circuit 210 may sample a first sampling voltage VSC21 based on the reference input voltage VREF received from the reference input terminal.

For example, in the second phase, the first switch S21 and the second switch S22 may be turned off, and the third switch S23 and the fourth switch S24 may be turned on. For example, the first switch S21 and the second switch S22 may be turned off in response to the second clock signal /CLK, and the third switch S23 and the fourth switch S24 may be turned on in response to the second clock signal /CLK. In the second phase, the reference sampling/operating circuit 210 may output the operating voltage VOP corresponding to a result of an operation on the first input voltage VP received from the first input terminal and the first sampling voltage VSC21. For example, in the second phase, the operating voltage VOP may be a voltage obtained by subtracting the first sampling voltage VSC21 from the first input voltage VP. In the second phase, because the first sampling voltage VSC21 is the reference input voltage VREF, the operating voltage VOP may be a voltage obtained by subtracting the reference input voltage VREF from the first input voltage VP (e.g., VOP=VP−VREF).

FIG. 10B is a circuit diagram illustrating a reverse reference sampling/operating circuit according to some example embodiments of the present disclosure. Referring to FIG. 10B, the reference sampling/operating circuit 210 may include the first switch S21, the second switch S22, the third switch S23, the fourth switch S24, and the first sampling capacitor SC21.

The reference sampling/operating circuit 210 may receive the first input voltage VP from the first input terminal, may receive the reference input voltage VREF from the reference input terminal, and may output the operating voltage VOP to the middle node NM.

A configuration and an operation of the reference sampling/operating circuit 210 of FIG. 10B may be the same as those of the reference sampling/operating circuit 210 of FIG. 10A except that, as the third switch S23 is connected between the first input terminal and the second node N22 and the fourth switch S24 is connected between the first node N21 and the middle node NM, the reference sampling/operating circuit 210 outputs a voltage obtained by adding the reference input voltage VREF to the first input voltage VP in the second phase as the operating voltage VOP (e.g., VOP=VP+VREF). Thus, additional description will be omitted to avoid redundancy.

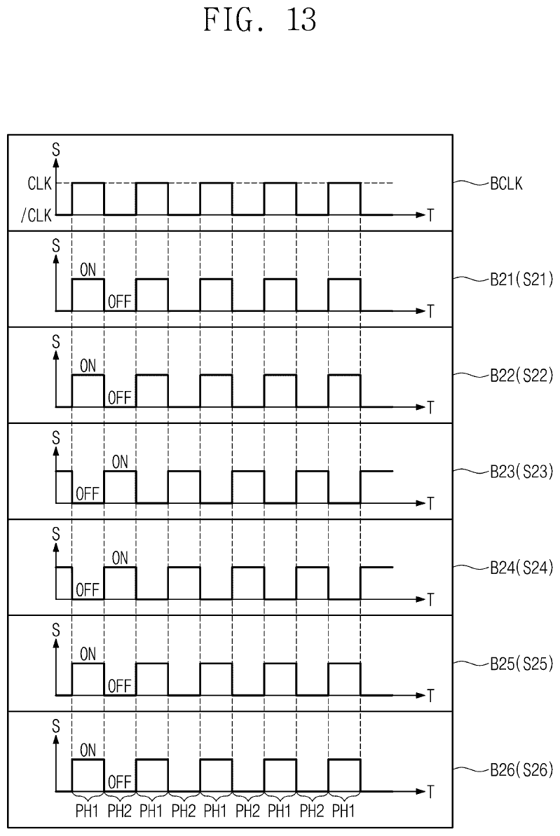

FIG. 11 is a circuit diagram illustrating a final sampling/comparing circuit according to some example embodiments of the present disclosure. Referring to FIG. 11, the final sampling/comparing circuit 220 may include a second sampling capacitor SC22, a first inverter INV21, a second inverter INV22, and a fifth switch S25.

The final sampling/comparing circuit 220 may receive the operating voltage VOP or the switching voltage VS from the middle node NM and may output the output voltage VOUT to the output terminal.

The second sampling capacitor SC22 may be connected between the middle node NM and a third node N23. The first inverter INV21 may be connected between the third node N23 and a fourth node N24. The second inverter INV22 may be connected between the fourth node N24 and the output terminal. The fifth switch S25 may be a switching element of the final sampling/comparing circuit 220. The fifth switch S25 and the first inverter INV21 may be connected in parallel between the third node N23 and the fourth node N24.

For example, in the first phase, the fifth switch S25 may be turned on. For example, the fifth switch S25 may be turned on in response to the first clock signal CLK. In the first phase, the final sampling/comparing circuit 220 may sample a second sampling voltage VSC22 based on the switching voltage VS received from the middle node NM. For example, in the first phase, when the fifth switch S25 is turned on, the third node N23 and the fourth node N24 may be short-circuited, and thus, an offset voltage VOS21 of the first inverter INV21 may be removed. That is, in the first phase, the first inverter INV21 may be set to an auto-zeroing state, and thus, the offset voltage VOS21 of the first inverter INV21 may be removed. Accordingly, in the first phase, the final sampling/comparing circuit 220 may sample, as the second sampling voltage VSC22, a voltage obtained by subtracting the offset voltage VOS21 of the first inverter INV21 from the switching voltage VS by using the second sampling capacitor SC22.

In some example embodiments, the offset voltage VOS21 of the first inverter INV21 may be a voltage of the third node N23 or the fourth node N24 when the first input terminal, the second input terminal, and the reference input terminal of the offset-free comparator 200 are short-circuited.

Referring to FIGS. 9 and 11, in the first phase, because the switching voltage VS is the second input voltage VN, the second sampling capacitor SC22 may sample, as the second sampling voltage VSC22, a voltage obtained by subtracting the offset voltage VOS21 of the first inverter INV21 from the second input voltage VN (e.g., VSC22=VN−VOS21).

In the first phase of the final sampling/comparing circuit 220, when the fifth switch S25 is turned on, an input terminal and an output terminal of the first inverter INV21, that is, the third node N23 and the fourth node N24 may be short-circuited. Herein, when the first inverter INV21 is a CMOS inverter, the first inverter INV21 between the third node N23 and the fourth node N24 may correspond to the circuit diagram illustrated in FIG. 4.

For example, in the second phase, the fifth switch S25 may be turned off. For example, the fifth switch S25 may be turned off in response to the second clock signal /CLK. In the second phase, the final sampling/comparing circuit 220 may output the output voltage VOUT corresponding to a result of comparing the operating voltage VOP received from the middle node NM and the second sampling voltage VSC22. For example, in the second phase, a third node voltage VN23 may be a voltage obtained by subtracting the second sampling voltage VSC22 from the operating voltage VOP, and the output voltage VOUT may correspond to a voltage in which the offset voltage VOS21 is removed from the third node voltage VN23.

Referring to FIGS. 10A and 11, in the second phase, because the operating voltage VOP is a voltage obtained by subtracting the reference input voltage VREF from the first input voltage VP, the third node voltage VN23 may be a voltage corresponding to “(the first input voltage VP minus the reference input voltage VREF) minus the second sampling voltage VSC22), that is, a voltage corresponding to “((the first input voltage VP minus the reference input voltage VREF) minus the second input voltage VN) plus the offset voltage VOS21 of the first inverter INV21” (e.g., VN23=((VP−VREF)−VN)+VOS21). Because the offset voltage VOS21 is already applied to the third node voltage VN23, the output voltage VOUT may be free from the offset voltage VOS21 of the first inverter INV21.

For example, when the first input voltage VP is greater than a voltage (VN+VREF) obtained by adding the reference input voltage VREF to the second input voltage VN, the output voltage VOUT may be logical high. As another example, when the first input voltage VP is smaller than the voltage (VN+VREF) obtained by adding the reference input voltage VREF to the second input voltage VN, the output voltage VOUT may be logical low.

Referring to FIGS. 10B and 11, in the second phase, because the operating voltage VOP is a voltage obtained by adding the reference input voltage VREF to the first input voltage VP, the third node voltage VN23 may be a voltage corresponding to “(the first input voltage VP plus the reference input voltage VREF) minus the second sampling voltage VSC22”, that is, a voltage corresponding to “((the first input voltage VP plus the reference input voltage VREF) minus the second input voltage VN) plus the offset voltage VOS21 of the first inverter INV21” (e.g., VN23=((VP+VREF)−VN)+VOS21). Because the offset voltage VOS21 is already applied to the third node voltage VN23, the output voltage VOUT may be free from the offset voltage VOS21 of the first inverter INV21.

For example, when the first input voltage VP is greater than a voltage (VN−VREF) obtained by subtracting the reference input voltage VREF from the second input voltage VN, the output voltage VOUT may be logical high. As another example, when the first input voltage VP is smaller than the voltage (VN−VREF) obtained by subtracting the reference input voltage VREF from the second input voltage VN, the output voltage VOUT may be logical low.

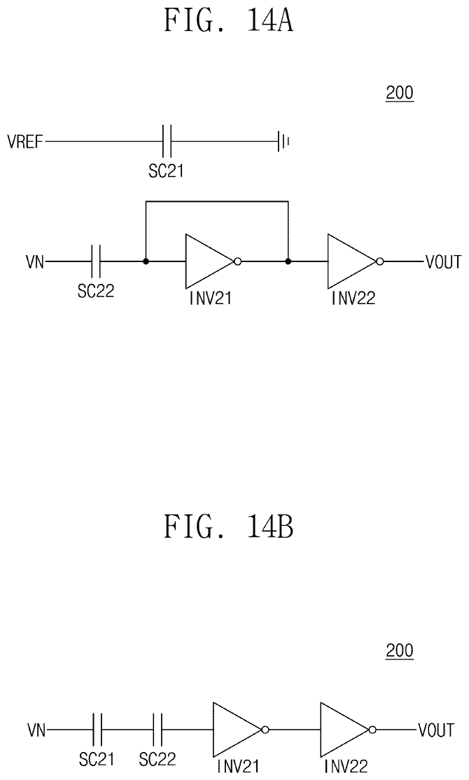

FIG. 12 is a circuit diagram illustrating the second switching circuit 230 according to some example embodiments of the present disclosure. Referring to FIG. 12, the second switching circuit 230 may include a sixth switch S26.

The second switching circuit 230 may receive the second input voltage VN from the second input terminal and may output the switching voltage VS to the middle node NM.

The sixth switch S26 may be a switching element of the second switching circuit 230. The sixth switch S26 may be connected between the second input terminal and the middle node NM.

For example, in the first phase, the sixth switch S26 may be turned on. For example, the sixth switch S26 may be turned on in response to the first clock signal CLK. In the first phase, the second switching circuit 230 may output the second input voltage VN received from the second input terminal to the middle node NM through the sixth switch S26. In the first phase, the switching voltage VS may be the second input voltage VN.

For example, in the second phase, the sixth switch S26 may be turned off. For example, the sixth switch S26 may be turned off in response to the second clock signal /CLK. In the second phase, the second switching circuit 230 may not output a voltage to the middle node NM.

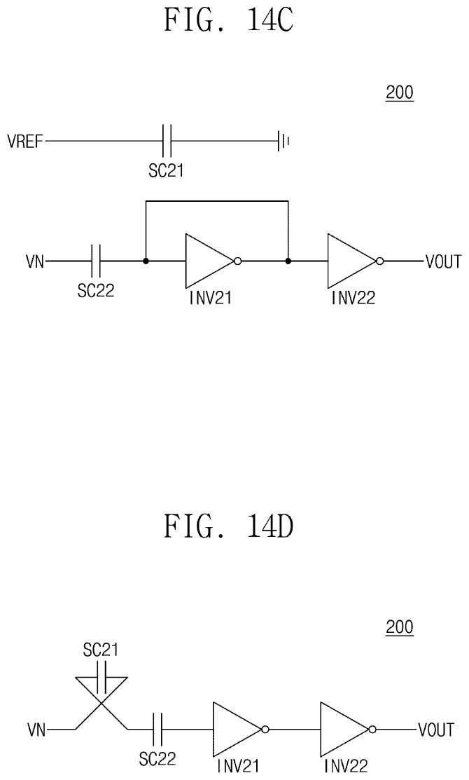

FIG. 13 illustrates states which a plurality of switches included in an offset-free comparator circuit capable of performing calculation have depending on a clock signal. In some example embodiments, states of the first to sixth switches S21 to S26 according to the first clock signal CLK and the second clock signal /CLK are illustrated in FIG. 13. The clock signal box BCLK shows a state of the clock signal. A first box B21 shows a state of the first switch S21. A second box B22 shows a state of the second switch S22. A third box B23 shows a state of the third switch S23. A fourth box B24 shows a state of the fourth switch S24. A fifth box B25 shows a state of the fifth switch S25. A sixth box B26 shows a state of the sixth switch S26. In FIG. 13, the horizontal axis represents a time “T”, and the vertical axis represents a state “S”.

Referring to FIG. 13, the states of the first to sixth switches S21 to S26 may be repeatedly changed in response to the first clock signal CLK and the second clock signal /CLK.

The first clock signal CLK and the second clock signal /CLK may be mutually repeated. The second clock signal /CLK may be an inverted signal of the first clock signal CLK. For example, the first clock signal CLK may be a logical high signal, and the second clock signal /CLK may be a logical low signal. For example, a response period to the first clock signal CLK may be the first phase PH1, and a response period to the second clock signal /CLK may be the second phase PH2.

The first switch S21, the second switch S22, the fifth switch S25, and the sixth switch S26 may be turned on in response to the first clock signal CLK and may be turned off in response to the second clock signal /CLK. The third switch S23 and the fourth switch S24 may be turned off in response to the first clock signal CLK and may be turned on in response to the second clock signal /CLK.

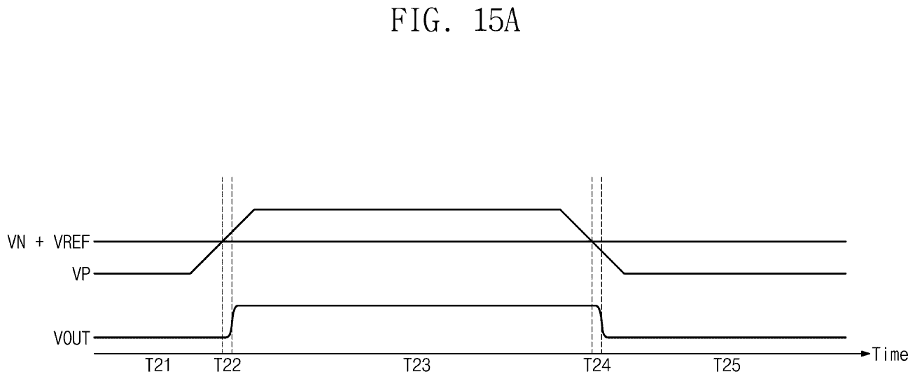

FIGS. 14A and 14B are circuit diagrams illustrating a first-phase circuit configuration and a second-phase circuit configuration of an offset-free comparator capable of performing forward calculation, according to some example embodiments of the present disclosure.

Referring to FIGS. 14A and 14B, in the first phase, the offset-free comparator 200 may sample the first sampling voltage VSC21, which is based on the reference input voltage VREF, by using the first sampling capacitor SC21 and may sample the second sampling voltage VSC22, which is based on the second input voltage VN, by using the second sampling capacitor SC22.

Also, in the second phase, the offset-free comparator 200 may output the output voltage VOUT corresponding to a result of comparing the first input voltage VP with a voltage (VN+VREF) obtained by adding the reference input voltage VREF to the second input voltage VN, to the output terminal through the first sampling capacitor SC21, the second sampling capacitor SC22, the first inverter INV21, and the second inverter INV22.

Accordingly, the offset-free comparator 200 removing an offset voltage by using auto-zeroing may output the accurate output voltage VOUT corresponding to the result of comparing the first input voltage VP with a voltage (VN+VREF) obtained by adding the reference input voltage VREF to the second input voltage VN.

FIGS. 14C and 14D are circuit diagrams illustrating a first-phase circuit configuration and a second-phase circuit configuration of an offset-free comparator capable of performing reverse calculation, according to some example embodiments of the present disclosure.

Referring to FIGS. 14C and 14D, in the first phase, an operation of the offset-free comparator 200 may be the same as that of the offset-free comparator 200 (refer to FIGS. 14A and 14B) capable of performing forward calculation. Thus, additional description will be omitted to avoid redundancy.

Also, in the second phase, the offset-free comparator 200 may output the output voltage VOUT corresponding to a result of comparing the first input voltage VP with a voltage (VN−VREF) obtained by subtracting the reference input voltage VREF from the second input voltage VN, to the output terminal through the first sampling capacitor SC21, the second sampling capacitor SC22, the first inverter INV21, and the second inverter INV22.

Accordingly, the offset-free comparator 200 removing an offset voltage by using auto-zeroing may output the accurate output voltage VOUT corresponding to the result of comparing the first input voltage VP with the voltage (VN−VREF) obtained by subtracting the reference input voltage VREF from the second input voltage VN.

That is, referring to FIGS. 14A to 14D, a comparator may be implemented which is capable of performing calculation by outputting the output voltage VOUT corresponding to a result of comparing a magnitude of a voltage obtained by performing an operation on two input voltages with a magnitude of the remaining input voltage.

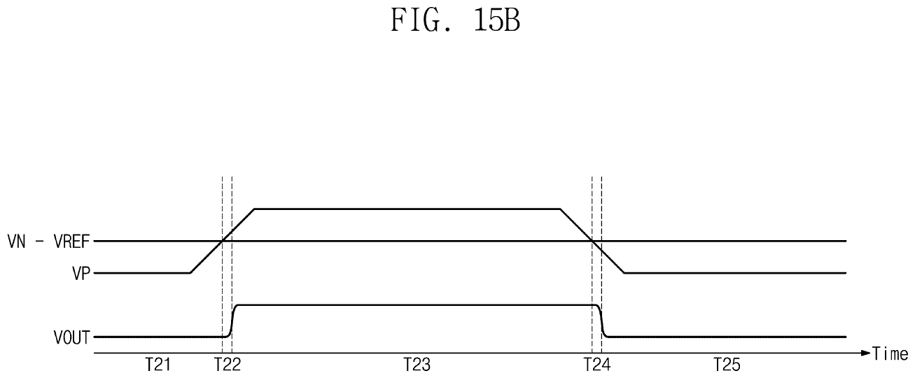

FIGS. 15A and 15B illustrate examples in which an offset-free comparator capable of performing an operation on variable input voltages operates. In FIG. 15A, the horizontal axis represents a time, and the vertical axis represents a voltage. In some example embodiments, an example in which the first input voltage VP, a voltage obtained by performing an operation on the second input voltage VN and the reference input voltage VREF, and the output voltage VOUT of the offset-free comparator 200 capable of performing calculation over time is illustrated in FIGS. 15A and 15B.

Referring to FIG. 15A, the output voltage VOUT of the offset-free comparator 200 may be logical high or logical low based on magnitudes of the first input voltage VP with a variable voltage level, the second input voltage VN, and the reference input voltage VREF. For convenience of description, an example in which a voltage (VN+VREF) obtained by adding the reference input voltage VREF to the second input voltage VN is fixed is illustrated in FIG. 15A, but the present disclosure is not limited thereto.

In a first time interval T21, when the first input voltage VP is smaller than the voltage (VN+VREF) obtained by adding the reference input voltage VREF to the second input voltage VN, the output voltage VOUT may be logical low.

In a second time interval T22, when the first input voltage VP is greater than voltage (VN+VREF) obtained by adding the reference input voltage VREF to the second input voltage VN, the output voltage VOUT may be logical low.

In a third time interval T23, when the first input voltage VP is greater than voltage (VN+VREF) obtained by adding the reference input voltage VREF to the second input voltage VN, the output voltage VOUT may be logical high.

In a fourth time interval T24, when the first input voltage VP is smaller than the voltage (VN+VREF) obtained by adding the reference input voltage VREF to the second input voltage VN, the output voltage VOUT may be logical high.

In a fifth time interval T25, when the first input voltage VP is smaller than the voltage (VN+VREF) obtained by adding the reference input voltage VREF to the second input voltage VN, the output voltage VOUT may be logical low.

Herein, in the second time interval T22, when the first input voltage VP is greater than the voltage (VN+VREF) obtained by adding the reference input voltage VREF to the second input voltage VN, the offset-free comparator 200 may output the output voltage VOUT corresponding to a comparison result of the first input voltage VP and the voltage (VN+VREF) obtained by adding the reference input voltage VREF to the second input voltage VN, that is, may output a logical low signal. Also, in the fourth time interval T24, when the first input voltage VP is smaller than the voltage (VN+VREF) obtained by adding the reference input voltage VREF to the second input voltage VN, the offset-free comparator 200 may output the output voltage VOUT corresponding to a comparison result of the first input voltage VP and the voltage (VN+VREF) obtained by adding the reference input voltage VREF to the second input voltage VN, that is, may output a logical high signal.

Immediately after (or simultaneously when) the first inverter INV21 is released from the auto-zeroing state while entering the second phase from the first phase, the final sampling/comparing circuit 220 may receive a voltage (VP−VREF) obtained by subtracting the reference input voltage VREF from the first input voltage VP from the middle node NM, and thus, a speed at which the output voltage VOUT of the offset-free comparator 200 changes may be improved.

Accordingly, the second time interval T22, that is, a time interval from a point in time when the first input voltage VP is greater than the second input voltage VN to a point in time when the offset-free comparator 100 outputs the output voltage VOUT corresponding to the comparison result of the first input voltage VP and the second input voltage VN, that is, a logical high signal may be shorter than that of the conventional analog comparator. Likewise, the fourth time interval T24, that is, a time interval from a point in time when the first input voltage VP is smaller than the second input voltage VN to a point in time when the offset-free comparator 100 outputs the output voltage VOUT corresponding to the comparison result of the first input voltage VP and the second input voltage VN, that is, a logical low signal may be shorter than that of the conventional analog comparator.

Referring to FIG. 15B, an operation of the offset-free comparator 200 may be the same as that of the offset-free comparator 200 of FIG. 15A except that the output voltage VOUT corresponding to the comparison result of the first input voltage VP and the voltage (VN−VREF) obtained by subtracting the reference input voltage VREF from the second input voltage VN is output. Thus, additional description will be omitted to avoid redundancy.

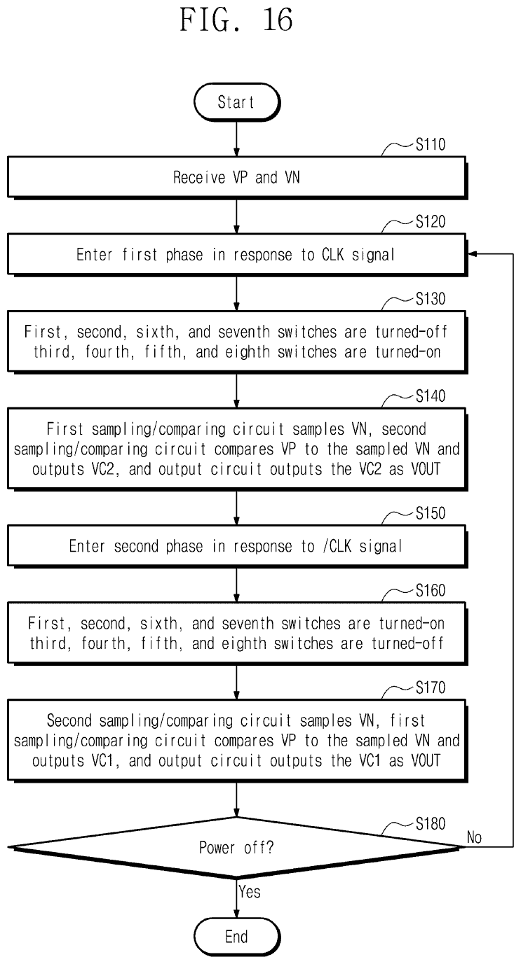

FIG. 16 illustrates an example of an operating method of an offset-free comparator with improved performance. Referring to FIG. 16, in operation S110, the offset-free comparator 100 with an improved response speed may receive the first input voltage VP and the second input voltage VN. For example, the first switching circuit 110 of the offset-free comparator 100 may receive the first input voltage VP and the second input voltage VN through a first input terminal and a second input terminal as shown in FIG. 1.

In operation S120, the offset-free comparator 100 may enter the first phase in response to the first clock signal CLK. For example, the offset-free comparator 100 may enter the first phase in response to the logical high signal.

In operation S130, the first switch S11, the second switch S12, the sixth switch S16, and the seventh switch S17 of the offset-free comparator 100 may be turned off, and the third switch S13, the fourth switch S14, the fifth switch S15, and the eighth switch S18 thereof may be turned on.

In operation S140, the first sampling/comparing circuit 120 may sample the second input voltage VN, the second sampling/comparing circuit 130 may output the second comparison voltage VC2 corresponding to a result of comparing the first input voltage VP with the sampled second input voltage VN, and the output circuit 140 may output the second comparison voltage VC2 as the output voltage VOUT.

In operation S150, the offset-free comparator 100 may enter the second phase in response to the second clock signal /CLK. For example, the offset-free comparator 100 may enter the second phase in response to the logical low signal.

In operation S160, the first switch S11, the second switch S12, the sixth switch S16, and the seventh switch S17 of the offset-free comparator 100 may be turned on, and the third switch S13, the fourth switch S14, the fifth switch S15, and the eighth switch S18 thereof may be turned off.

In operation S170, the second sampling/comparing circuit 130 may sample the second input voltage VN, the first sampling/comparing circuit 120 may output the first comparison voltage VC1 corresponding to a result of comparing the first input voltage VP with the sampled second input voltage VN, and the output circuit 140 may output the first comparison voltage VC1 as the output voltage VOUT.

In operation S180, whether a power supplied to the offset-free comparator 100 is turned off may be determined. When the power supplied to the offset-free comparator 100 is turned off, the offset-free comparator 100 may terminate the operation. When the power supplied to the offset-free comparator 100 is not turned off, the offset-free comparator 100 may return to operation S120 and may then repeat the above process depending on the repeated clock signal.

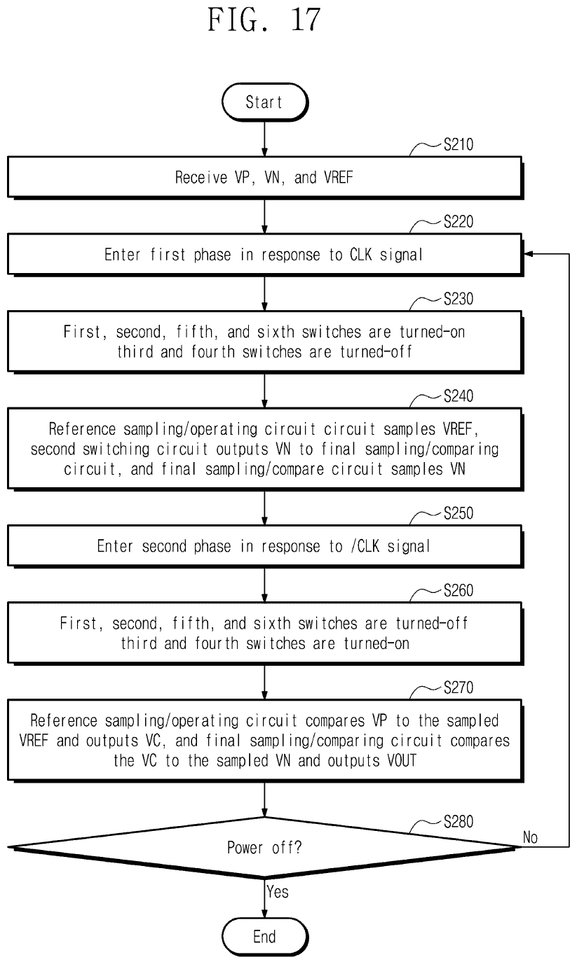

FIG. 17 illustrates an example of an operating method of an offset-free comparator capable of performing calculation. Referring to FIG. 17, in operation S210, the offset-free comparator 200 capable of performing calculation may receive the first input voltage VP, the second input voltage VN, and the reference input voltage VREF. For example, the reference sampling/operating circuit 210 of the offset-free comparator 200 may receive the first input voltage VP and the reference input voltage VREF respectively through a first input terminal and a reference input terminal, and the second switching circuit 230 may receive the second input voltage VN through a second input terminal, as shown in FIG. 9.

In operation S220, the offset-free comparator 200 may enter the first phase in response to the first clock signal CLK. For example, the offset-free comparator 200 may enter the first phase in response to the logical high signal.

In operation S230, the first switch S21, the second switch S22, the fifth switch S25, and the sixth switch S26 of the offset-free comparator 200 may be turned on, and the third switch S23 and the fourth switch S24 thereof may be turned off.

In operation S240, the reference sampling/operating circuit 210 may sample the reference input voltage VREF, the second switching circuit 230 may output the second input voltage VN to the final sampling/comparing circuit 220, and the final sampling/comparing circuit 220 may sample the second input voltage VN.

In operation S250, the offset-free comparator 200 may enter the second phase in response to the second clock signal /CLK. For example, the offset-free comparator 200 may enter the second phase in response to the logical low signal.

In operation S260, the first switch S21, the second switch S22, the fifth switch S25, and the sixth switch S26 of the offset-free comparator 200 may be turned off, and the third switch S23 and the fourth switch S24 thereof may be turned on.

In operation S270, the reference sampling/operating circuit 210 may output the operating voltage VOP corresponding to a result of comparing the first input voltage VP and the sampled reference input voltage VREF, and the final sampling/comparing circuit 220 may output the output voltage VOUT corresponding to the result of comparing the first input voltage VP and the sampled second input voltage VN. For example, the output voltage VOUT may be a voltage corresponding to a result of comparing the first input voltage VP with a voltage (VN+VREF) obtained by adding the reference input voltage VREF to the second input voltage VN. As another example, the output voltage VOUT may be a voltage corresponding to a result of comparing the first input voltage VP with a voltage (VN−VREF) obtained by subtracting the reference input voltage VREF from the second input voltage VN. That is, the offset-free comparator 200 may output a voltage corresponding to a result of comparing the first input voltage VP with a result of performing an operation on the second input voltage VN and the reference input voltage VREF.

In operation S280, whether a power supplied to the offset-free comparator 200 is turned off may be determined. When the power supplied to the offset-free comparator 200 is turned off, the offset-free comparator 200 may terminate the operation. When the power supplied to the offset-free comparator 200 is not turned off, the offset-free comparator 200 may return to operation S220 and may then repeat the above process depending on the repeated clock signal.

According to some example embodiments of the present disclosure, an offset-free comparator circuit removing an offset by using auto-zeroing is provided. Accordingly, a comparator circuit with an improved response speed and improved accuracy and a comparator circuit capable of performing calculation accurately are provided.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A comparator comprising:
a switching circuit configured to receive a first input voltage and a second input voltage respectively from a first input terminal and a second input terminal, and to output a first switching voltage and a second switching voltage respectively to a first switching node and a second switching node;
a first sampling/comparing circuit configured to receive the first switching voltage from the first switching node and to output a first comparison voltage to a first comparison node;
a second sampling/comparing circuit configured to receive the second switching voltage from the second switching node and to output a second comparison voltage to a second comparison node; and
an output circuit configured to receive the first comparison voltage and the second comparison voltage respectively from the first comparison node and the second comparison node, and to output an output voltage to a single output terminal,
wherein the comparator is configured to operate in a first phase and a second phase in response to a clock signal,
wherein each of the first input voltage and the second input voltage have a variable voltage level,
wherein the switching circuit is configured to
output the second input voltage as the first switching voltage and output the first input voltage as the second switching voltage during the first phase, and
output the first input voltage as the first switching voltage and output the second input voltage as the second switching voltage during the second phase,
wherein the first sampling/comparing circuit is configured to
sample a first sampling voltage based on the second input voltage during the first phase, and
output the first comparison voltage corresponding to a result of comparing the first input voltage with the first sampling voltage during the second phase,
wherein the second sampling/comparing circuit is configured to
sample a second sampling voltage based on the second input voltage during the second phase, and
output the second comparison voltage corresponding to a result of comparing the first input voltage with the second sampling voltage during the first phase, and
wherein the output circuit is configured to
output the output voltage corresponding to the second comparison voltage during the first phase, and
output the output voltage corresponding to the first comparison voltage during the second phase.

2. The comparator of claim 1, wherein the switching circuit includes:
a first switch connected between the first input terminal and the first switching node;
a second switch connected between the second input terminal the second switching node;
a third switch connected between the first input terminal and the second switching node; and
a fourth switch connected between the second input terminal and the first switching node,
wherein during the first phase, the switching circuit is configured to turn off the first switch and the second switch, and turn on the third switch and the fourth switch, and
wherein during the second phase, the switching circuit is configured to turn on the first switch and the second switch, and turn off the third switch and the fourth switch.

3. The comparator of claim 1, wherein the first sampling/comparing circuit includes:
a sampling capacitor connected between the first switching node and a first node;
a first inverter connected between the first node and a second node;
a second inverter connected between the second node and the first comparison node; and
a switch,
wherein the switch and the first inverter are connected in parallel between the first node and the second node, and
wherein the first sampling/comparing circuit is configured to turn on the switch during the first phase and turn off the switch during the second phase.

4. The comparator of claim 3, wherein during the first phase, the first sampling/comparing circuit is configured to sample a voltage obtained by subtracting an offset voltage of the first inverter from the second input voltage to provide the first sampling voltage by using the sampling capacitor, and
during the second phase the first sampling/comparing circuit is configured to output through the first inverter and the second inverter a voltage corresponding to a voltage obtained by subtracting the first sampling voltage from the first input voltage as the first comparison voltage.

5. The comparator of claim 4, wherein the first comparison voltage has a logical high level when the first input voltage is greater than the second input voltage and has a logical low level when the first input voltage is smaller than the second input voltage.

6. The comparator of claim 3, wherein the first inverter includes a CMOS inverter including an input terminal connected to the first node and an output terminal connected to the second node, and
wherein the switch is configured to short-circuit the input terminal and the output terminal of the CMOS inverter when turned on during the first phase.

7. The comparator of claim 1, wherein the second sampling/comparing circuit includes:
a sampling capacitor connected between the second switching node and a first node;
a first inverter connected between the first node and a second node;
a second inverter connected between the second node and the second comparison node; and
a switch,
wherein the switch and the first inverter are connected in parallel between the first node and the second node, and
wherein the second sampling/comparing circuit is configured to turn off the switch during the first phase and turn on the switch during the second phase.

8. The comparator of claim 7, wherein during the second phase the second sampling/comparing circuit is configured to sample a voltage obtained by subtracting an offset voltage of the first inverter from the second input voltage to provide the second sampling voltage by using the sampling capacitor, and
during the first phase the second sampling/comparing circuit is configured to output through the first inverter and the second inverter a voltage corresponding to a voltage obtained by subtracting the second sampling voltage from the first input voltage as the second comparison voltage.

9. The comparator of claim 8, wherein the second comparison voltage has a logical high level when the first input voltage is greater than the second input voltage and has a logical low level when the first input voltage is smaller than the second input voltage.

10. The comparator of claim 1, wherein the output circuit includes:
a first switch connected between the first comparison node and the single output terminal; and
an second switch connected between the second comparison node and the single output terminal,
wherein the output circuit is configured to turn off the first switch and turn on the second switch during the first phase, and
wherein the output circuit is configured to turn on the first switch and turn off the second switch during the second phase.

11. A comparator comprising:
a first switch connected between a first input terminal and a first switching node, the first switch configured to receive a first input voltage at the first input terminal;
a second switch connected between a second input terminal and a second switching node, the second switch configured to receive a second input voltage at the second input terminal;
a third switch connected between the first input terminal and the second switching node;
a fourth switch connected between the second input terminal and the first switching node;
a first sampling capacitor connected between the first switching node and a first node;
a first inverter connected between the first node and a second node;
a second inverter connected between the second node and a first comparison node;
a fifth switch connected in parallel with the first inverter and between the first node and the second node;
a second sampling capacitor connected between the second switching node and a third node;
a third inverter connected between the third node and a fourth node;
a fourth inverter connected between the fourth node and a second comparison node;
a sixth switch connected in parallel with the third inverter and between the third node and the fourth node;
a seventh switch connected between the first comparison node and a single output terminal, the single output terminal configured to output an output voltage; and
an eighth switch connected between the second comparison node and the single output terminal,
wherein the comparator is configured to operate in a first phase and a second phase in response to a clock signal,
wherein each of the first input voltage and the second input voltage have a variable voltage level,
wherein during the first phase, the comparator is configured to turn off the first switch, the second switch, the sixth switch, and the seventh switch, and turn on the third switch, the fourth switch, the fifth switch, and the eighth switch, and
wherein during the second phase, the comparator is configured to turn on the first switch, the second switch, the sixth switch, and the seventh switch, and turn off the third switch, the fourth switch, the fifth switch, and the eighth switch.

12. A comparator comprising:
a reference sampling/operating circuit configured to receive a first input voltage and a reference input voltage respectively from a first input terminal and a reference input terminal, and to output an operating voltage to a middle node;
a switching circuit configured to receive a second input voltage from a second input terminal and to output a switching voltage to the middle node; and
a sampling/comparing circuit configured to receive the operating voltage or the switching voltage from the middle node, and to output an output voltage to an output terminal,
wherein the comparator is configured to operate in a first phase and a second phase in response to a clock signal,
wherein each of the first input voltage, the second input voltage, and the reference input voltage have a variable voltage level,
wherein the reference sampling/operating circuit is configured to
sample the reference input voltage during the first phase, and
output a result of performing an operation on the first input voltage and the sampled reference input voltage as the operating voltage during the second phase,
wherein the switching circuit is configured to
output the second input voltage as the switching voltage during the first phase, and
provide no output to the middle node during the second phase, and
wherein the sampling/comparing circuit is configured to
sample a sampling voltage based on the second input voltage during the first phase, and
output the output voltage corresponding to a result of comparing the operating voltage and the sampling voltage to the output terminal during the second phase.

13. The comparator of claim 12, wherein the reference sampling/operating circuit includes:
a first switch connected between the reference input terminal and a first node;
a sampling capacitor connected between the first node and a second node;
a second switch connected between the second node and a ground terminal;
a third switch connected between the first input terminal and the first node; and
a fourth switch connected between the second node and the middle node,
wherein during the first phase, the reference sampling/operating circuit is configured to turn on the first switch and the second switch, and turn off the third switch and the fourth switch, and
wherein during the second phase, the reference sampling/operating circuit is configured to turn off the first switch and the second switch, and turn on the third switch and the fourth switch.

14. The comparator of claim 13, wherein during the first phase the reference sampling/operating circuit is configured to sample the reference input voltage using the sampling capacitor, and
during the second phase the reference sampling/operating circuit is configured to output a voltage obtained by subtracting the sampled reference input voltage from the first input voltage as the operating voltage.

15. The comparator of claim 12, wherein the reference sampling/operating circuit includes:
a first switch connected between the reference input terminal and a first node;
a sampling capacitor connected between the first node and a second node;
a second switch connected between the second node and a ground terminal;
a third switch connected between the first input terminal the second node; and
a fourth switch connected between the first node and the middle node,
wherein during the first phase, the reference sampling/operating circuit is configured to turn on the first switch and the second switch, and turn off the third switch and the fourth switch, and
wherein during the second phase, the reference sampling/operating circuit is configured to turn off the first switch and the second switch, and turn on the third switch and the fourth switch.

16. The comparator of claim 15, wherein during the first phase the reference sampling/operating circuit is configured to sample the reference input voltage by using the sampling capacitor, and
during the second phase the reference sampling/operating circuit is configured to output a voltage obtained by adding the sampled reference input voltage to the first input voltage as the operating voltage.

17. The comparator of claim 12, wherein the sampling/comparing circuit includes:
a sampling capacitor connected between the middle node and a first node;
a first inverter connected between the first node and a second node;
a second inverter connected between the second node and the output terminal; and
a switch,
wherein the switch and the first inverter are connected in parallel between the first node and the second node, and
wherein the sampling/comparing circuit is configured to turn on the switch during the first phase and turn off the switch during the second phase.

18. The comparator of claim 17, wherein during the first phase the sampling/comparing circuit is configured to sample a voltage obtained by subtracting an offset voltage of the first inverter from the second input voltage to provide a sampling voltage, and
during the second phase the sampling/comparing circuit is configured to output through the first inverter and the second inverter a voltage corresponding to a voltage obtained by subtracting the sampling voltage from the operating voltage as the output voltage.

19. The comparator of claim 18, wherein the output voltage has a logical high level when the operating voltage is greater than the second input voltage and has a logical low level when the output voltage is smaller than the second input voltage.

20. The comparator of claim 12, wherein the switching circuit includes a switch connected between the second input terminal and the middle node, and
wherein switching circuit is configured to turn on the switch during the first phase and turn off the switch during the second phase.
